(19) United States
(12) Patent Application Publication
(10) Pub. No.: US 2020/0124664 A1
(43) Pub. Date: Apr. 23, 2020

(54) ELECTRICAL TEST APPARATUS HAVING ADJUSTABLE CONTACT PRESSURE

(71) Applicant: KES SYSTEMS & SERVICE (1993) PTE, LTD., Singapore (SG)

(72) Inventors: Hock Soon Sim, Singapore (SG); Fook Seng Manfred Kong, Singapore (SG)

(73) Assignee: KES SYSTEMS & SERVICE (1993) PTE, LTD., Singapore (SG)

(21) Appl. No.: 16/500,281

(22) PCT Filed: Mar. 28, 2018
(86) PCT No.: PCT/SG2018/050143

§ 371 Date: Oct. 2, 2019

Related U.S. Application Data
(60) Provisional application No. 62/480,882, filed on Apr. 3, 2017.

(51) Int. Cl. G01R 31/28; G01R 1/073; G01R 1/067

(52) U.S. Cl. CPC G01R 31/2891; G01R 1/07328; G01R 1/07378; G01R 1/06755; G01R 1/07357

(57) ABSTRACT

A test assembly with adjustable contact pressure feature for test on wafer. The vertical type test assembly provides electrical contact pins where the force with which the pins press against the contacts is adjustable. This allows for easy correction of the contact force of the contact element with the wafer's test pad.

### BACKGROUND OF THE INVENTION

Wafers containing thousands to a few hundred thousand integrated circuit die are subjected to various electrical tests. These electrical tests are designed to identify bad die on the wafer prior to singulation into individual die and insertion into final package. Examples of such packages include a quad flat package (QFP), quad flat no lead packages (QFN), ball grid array (BGA), wafer level chip scale packages (WLCSP) etc. The separation of good and bad individual die is carried out in a wafer sort test system.

A typical wafer sort test systems set up in a test cell consists of a tester for generating various electrical test signals, a test head for transferring the signals to the prober interface board, a prober interface board to transfer signals to the probe card. A probe card for making temporary electrical contact with the wafer and a wafer prober for handling and positioning the wafer to the probe card.

During the wafer sort test, the tester generates and measures various electrical test signals that consist of specific combinations of voltage, current and frequency. These electrical test signals are transmitted from the tester to the test head, to the prober interface board, to the probe card and then to one or more integrated circuits on the wafer. The integrated circuit response to electrical signals such as voltage, current and frequency will be measured, analyzed and compared by the tester. These received electrical values of the specific integrated circuit that do not meet specification will be identified as ‘bad’ in the software.

Probe cards consist of a PCB and a probe head (referred to herein as a test assembly or prober) that contains contact elements such as probe needles for making temporary electrical contact with the die pads on the wafer or a group of die pads on the wafer. The test assembly aligns the wafer's X-Y position with reference to the probe card's position prior to the start of any electrical test to the wafer. Such prober will then bring together the wafer to the probe card in Z-up direction until the probe needles touch the wafer pads. The assembly will then overdrive a further Z-up distance (typically a few mils) to make sure all probe needles are brought into contact with the respective contact pads with sufficient force. Sufficient force is adequate force to ensure good electrical contact between the probe needles and the contact pads.

The contact element exchanges the electrical signal from the tester through the probe needles. Once the electrical test is completed on that die, the wafer is stepped in sequence to the rest of the untested die.

One problem that arises in electrical test assemblies is that the die pad surface on the wafer typically has a layer of metal oxide formed thereon by oxidation from the reaction with air. This metal oxide layer adversely affects the conductance of electricity because it presents a high electrical contact resistance during electrical testing. To ensure accurate electrical test results, this layer of oxide must be penetrated to expose the underlying metal.

To penetrate the oxide layers, the probe needles should be placed into contact with the electrical contacts with some gram force (or other such measure) that will allow the probe needles to penetrate or punch through the oxide layer of the electrical contact and into contact with the underlying metal surface. If the force is too little, the probe needles may not punch through the oxide completely. Too much force may cause the metal contact pad to crack. In current test apparatus, the operator can reduce the contact force by reducing the overdrive in the Z-up direction but such adjustments may be at the expense of co-planarity of the probe head and the wafer (and therefore non-uniform contact between the plurality of the probe needles and the plurality of contact pads). The contact force between the probe needles and the contact pads is pre-determined during design of the apparatus and built in to the assembly when manufactured. As such, the contact force is fixed and cannot be changed unless the overall design of the test apparatus is changed.

Consequently, based on the problems of using a fixed contact force to bring the probe needles into contact with the contact pads, a solution to such problems is sought.

### BRIEF SUMMARY OF THE INVENTION

A test assembly in which the contact force between the probe needles and the contact pads can be varied is described herein. Such contact force between the probe needles and contact pads can be adjusted by the operator at the production or testing site. The contact force is either manually adjusted or fine-tuned by the operator, by removing or adding spacers or turning screws provided for force adjustment. Another benefit of the test assembly described herein is the easy replacement of the probe needles by moving the locating plates (the position of some of which is adjustable in the Z-direction).

In one embodiment the test assembly includes a plurality of guide plates at least one of which can be moved in a Z-direction compared with a plane of a substrate for a test assembly, where the plurality of guide plates each have a plurality of through holes. The plurality of guide plates at least also includes a plurality of probe needles, the probe needles extending from a substrate end of the test assembly toward a distal end, where the probe needles at the distal end are brought into contact with contact pads disposed on a wafer to be tested by the test assembly, thereby translating force to the probe needles in contact with contact pads disposed on the substrate. The plurality of guide plates at least also includes at least one guide plate moveable in the Z-direction can be moved closer to or further away from at least one other of the plurality of guide plates in the test assembly thereby adjusting a distance between the at least one guide plate moveable in the Z-direction and an opposing guide plate of the plurality of guide plates. The distance between the guide plate moveable in the Z-direction and the at least one other guide plate determines a force with which the probe needles contact the contact pads on the wafer and contact pads on the substrate.

In some embodiments, the substrate is one of a printed circuit board and a space transformer. The probe needles extend through the through holes of the guide plates. A portion of each of the plurality of probe needles are disposed in a sleeve of non-conducting electrical insulation. The plurality of probe needles each have a first diameter and the portion of the probe needles disposed in the sleeve of non-conducting electrical insulation have a second diameter, the first diameter being smaller than the second diameter. In one embodiment a bottom guide plate is interposed between the guide plate moveable in the Z-direction and the wafer where a diameter of the through holes in the bottom guide plate is less than the diameter of the through holes in the guide plate moveable in the Z-direction such that the probe needles disposed in the sleeve and having the second diameter will extend through the through holes of the guide plate moveable in the Z-direction but will not extend through the through holes of the bottom guide plate and where the probe needles having the first diameter will extend through the through holes of the guide plate moveable in the Z-direction and also through the through holes of the bottom guide plate. As such the plurality of probe needles are retained in the test assembly by the bottom guide plate. The guide plate moveable in the Z-direction can be advanced toward or away from an opposing guide plate, where a greater distance between the guide plate moveable in the Z-direction and the bottom guide plate is reflective of a lesser contact force between the probe needles and the wafer contact pads and a lesser distance between the guide plate moveable in the Z-direction and the bottom guide plate is reflective of a greater contact force between the probe needles and the wafer contact pads. In one embodiment, the test assembly includes an adjustment mechanism that permits a position of the guide plate moveable in the Z-direction relative to the opposing guide plate to be adjusted prior to the wafer contact pads being brought into contact with the probe needles, where the position is held when the wafer contact pads are brought into contact with the probe needles. In one exemplary embodiment, the adjustment mechanism is a threaded rod along which the guide plate moveable in the z-direction is advanced for adjustment and threaded nuts that will retain the guide plate moveable in the z-direction in place. In another embodiment, the distance between opposing plates is adjusted by adding or removing a shim (or a plurality of shims) or a spacer (or a plurality of spacers) thereby increasing or decreasing the distance between the opposing guide-plates in the Z-direction.

In one embodiment, the test assembly includes a top guide plate interposed between the guide plate moveable in the Z-direction and the substrate and a bottom guide plate that is interposed between the guide plate moveable in the Z-direction and the wafer, where the top guide plate is removably fastened to the substrate. In one embodiment the probe needles are a noble metal (e.g. platinum, gold, etc.) or a refractory metal (e.g. tungsten).

Also described herein is a method for operating a test assembly including: providing the test assembly where the plurality of guide plates includes a top guide plate interposed between the guide plate moveable in a Z-direction and the substrate and a bottom guide plate that is interposed between the guide plate moveable in the Z-direction and the wafer. According to the method the contact pads of the wafer are advanced into contact with the probe needles. The contact pads of the wafer are continued to be advanced past a point of initial contact with the probe needles such that a portion of the probe needles between the bottom guide plate and the guide plate moveable in the Z-direction bend in response to the force between the wafer contact pads and the probe needles. The method further includes adjusting a distance between a position of the guide plate moveable in the Z-direction relative to the top guide plate or bottom guide plate, wherein the adjusting step is prior to the advancing step. The adjusting step includes advancing the guide plate moveable in the Z-direction along a rod or spline.

### BRIEF DESCRIPTION OF THE DRAWINGS

FIG. 1 illustrates a perspective view of one embodiment of the present invention with the middle plate and a bottom plate adjustable in the Z-direction;

FIG. 2 is a side view of one embodiment of the test apparatus described herein illustrating the buckling distance between two plates;

FIG. 3 is a cut away side view of the test apparatus of FIG. 2 with the probe needles brought into forceful coupling with the contact pads, thereby buckling;

FIG. 4 illustrates an adjustment of the buckling distance of the test apparatus in FIG. 3 in which the buckling distance is increased;

FIG. 5 illustrates the effect on bucking of a change in buckling distance;

FIG. 6 illustrates an adjustment in the buckling distance of the test apparatus in FIG. 3 in which the buckling distance is decreased;

FIG. 7 illustrates how the change in buckling distance affects buckling;

FIG. 8 illustrates how probe needles can be removed according to one embodiment;

FIG. 9a illustrates how probe needles can be inserted according to a second embodiment.

### DETAILED DESCRIPTION

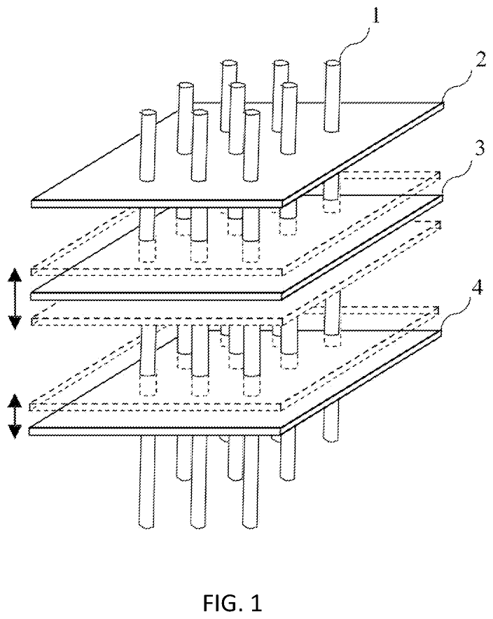

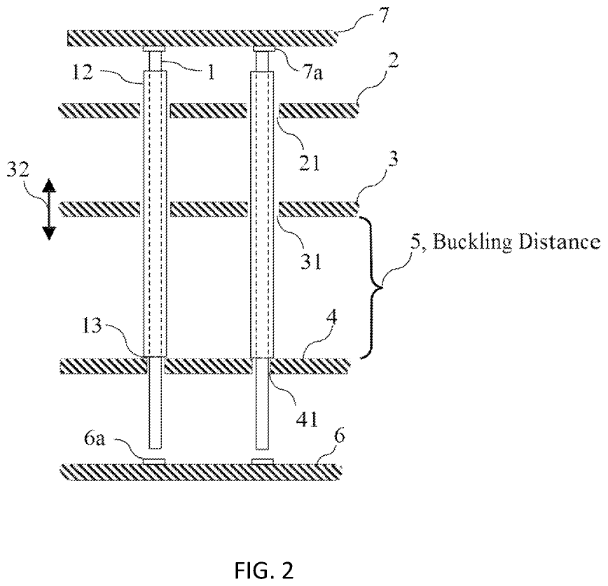

Referring to FIGS. 1 and 2, those figures illustrate a test assembly having a plurality of vertical probe needles 1, one or more top locating guide plates 2, one or more middle locating guide plates 3 and one or more bottom locating guide plates 4.

Locating guide plates are non-electrically conductive plates 2, 3 and 4 with holes for guiding vertical probe needles 1 and holding the needles vertically upright. The probe needles 1 are made out of a noble metal or noble alloy, or any conducting metal with a non-electrically conductive insulation 12 coated around the body of the probe needle forming a sleeve through which the probe needle 1 extends from both ends. When the probe needle is held vertically by the locating guide plates, probe needles extend from either end of the non-electrical conductive insulation 12. The bottom ends of the probe needles 1 are in electrical contact with the pads on the wafer and the top ends of the probe needles 1 are in contact with the electrical contact pads (7a) of the space transformer or PCB. The thickness of the non-electrically conductive insulation 12 functions as a stop 13 for the probe needle 1, by preventing the portion of the probe needle that extends beyond the non-conductive insulation 12 in the direction of the lower plate 4 from advancing more than a predetermined distance beyond lower plate 4.

The probe needles are dimensioned such that they provide a sufficient amount of conductance for the test assembly. The amount of conductance required for a specific apparatus is largely a matter of design choice and is not discussed in detail herein. The probe needles are dimensioned to be resilient. As described in detail below, the apparatus allows for the probe needles to bend as a test wafer is advanced into contact with the probe needles for testing. After testing, when the test wafer is removed from contact with the probe needles, the probe needles relax to an essentially straight orientation. One skilled in the art can select probe needle materials and dimensions to achieve these objectives. In one exemplary embodiment, the probe needles are one of palladium, silver, platinum, rhodium, tungsten and gold with diameters of about 20 μm to about 200 μm.

The probe needles 1 (and the surrounding non-electrically conductive insulation for those guide holes with sufficient diameter for the probe needles 1 surrounded by non-electrically conductive insulation to pass therethrough) are retained vertically by the guide holes 21, 31 and 41 in respective guide plates 2, 3 and 4. The vertical probe needles 1 pass through the holes 21 in the top guide plate 2 through the holes 31 in middle guide plate 3 and then through the holes 41 in lower guide plate 4. The holes 41 in the bottom guide plate 41 are smaller in diameter than the holes 21 and 31 in the top 2 and middle 3 guide plates.

The smaller diameter holes 41 serve as a stop for the vertical probe needle 1 thereby retaining the probe needle in the test assembly structure. Because the probe needles are movable, they will fall out through the bottom hole 41 if not retained in the structure. After the probe needles 1 are slid completely into the test assembly such that the end portion of the conductive insulation 12 is in contact with the bottom guide plate 4 at 13, the top end of the probe needles are covered by space transformer or PCB (7). The top end of the probe needles remain in contact with the pads (7a) of the transformer or PCB. The test assembly is fastened to the space transformer or PCB (7) with screws (not shown) or bolts or other conventional fastening mechanisms well known to the skilled person. The screws or bolts fasten PCB (7) with top locating plate 2. The middle 3 and lower 4 guide plates are not so fastened. When the probe needles need to be replaced, the test assembly can be taken apart by removing the screws or bolts and separating the assembly from the transformer or PCB.

The stopper 13 results from the fact that the non-electrically conductive insulation 12 on the probe needles forms a structure with a diameter that exceeds the diameter of the hole 41 in the bottom guide plate 4. The probe needle/non-electrically conductive insulation structure assembly cannot pass through the hole 41. Therefore the probe needle/non-electrically conductive structure is held in the assembly by the reduced diameter hole 41.

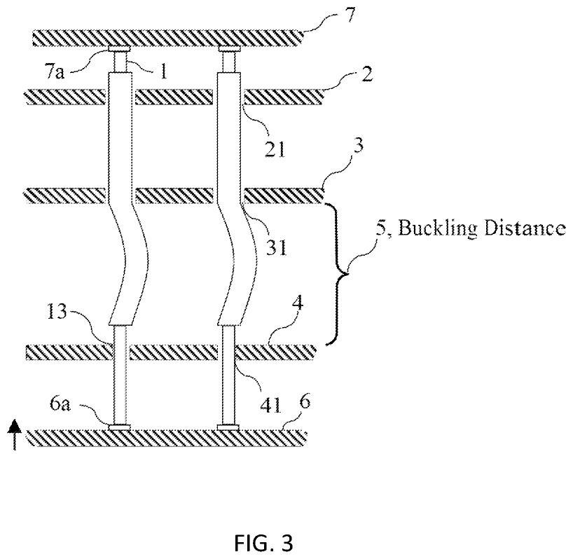

Referring to FIG. 3, during operation, the wafer 6 having the contact pads 6a thereon is being moved up toward the test assembly, making contact of the wafer's pad 6a to the vertical probe needle 1 of the test assembly. The wafer 6 is pushed upward and the body of the vertical probe needles 1 buckle or axially deflect between the middle locating guide plate 31 and bottom locating guide plate 13 because the vertical probe needles cannot move upward in response to the force applied to the distal end of the vertical probe needles by the rising wafer 6. This action causes the vertical probe needle 1 to exert contact force at both ends (i.e. the end in contact with contact 7a and the end in contact with 6a). The contact force acting onto the contact pad 6a, 7a is based on and related to the buckling distance 5. This provides stable electrical contact to conduct electricity from the contact pads 7a of the space transformer or PCB 7 with the wafer's contact pads 6a. After operation, the wafer is moved down or away from contact with the probe needles 1 and the vertical probe needle reverts back to its non-buckled or non-deflected state as illustrated in FIG. 2.

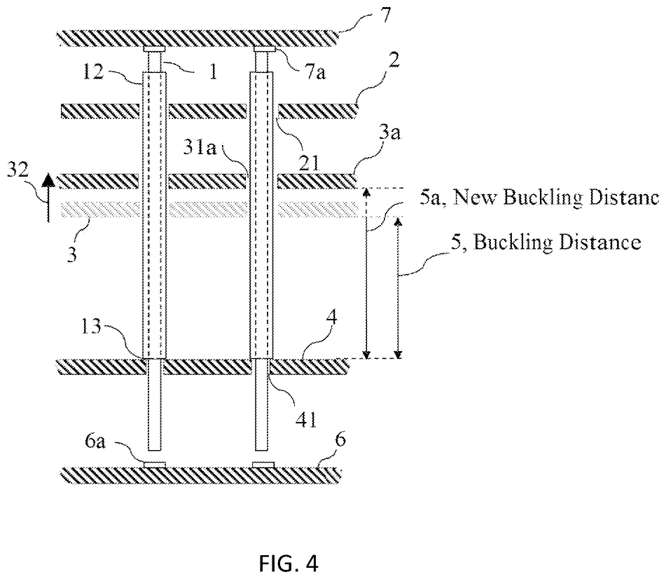

Referring to FIG. 4, the middle locating guide plate 3 is slide-able or moveable in the Z-plane 32. As a result the buckling distance 5 (i.e. the distance between middle guide plate 3 with larger through holes and lower guide plate 4 with smaller through holes) is adjustable. Moving the middle locating guide plate 3 up in Z-plane 32 (i.e. increasing the distance between the middle guide plate 3 and the lower guide plate 4), the buckling distance 5 increases, and the buckling distance decreases when the middle guide plate 3 is moved down in the Z-direction (i.e. decreasing the distance between the middle guide plate 3 and the lower guide plate 4).

Increasing the buckling distance from 5 to 5a causes the vertical probe needle to have a longer vertical distance between guide plates 3 and 4. This increased buckling distance between middle guide plate 3a and bottom locating guide plate 4 lowers the contact force between the probe needles 1 and the pads 6a. This is because less force is required to cause the probe needles to buckle when the span between the middle guide plate 3a and the lower guide plate 4 is larger.

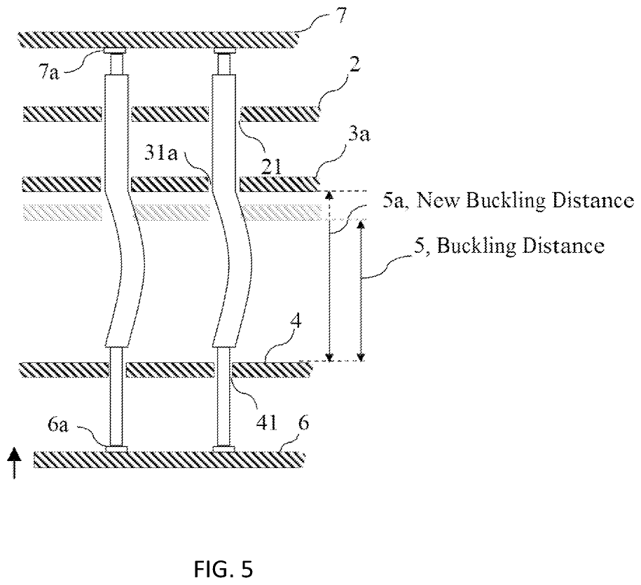

Referring to FIG. 5, during operation, the wafer 6 is moved up toward the test assembly, making contact between the wafer pads 6a and the vertical probe needle 1 of the test assembly. The wafer 6 is advanced further upward and the body of the probe needles buckle or axially deflect along the linear distance between the middle guide plate 3a and the lower guide plate 4. Note that the longer buckling distance 5a causes the body of the probe needles to buckle or axially deflect at a higher point in the structure compared to the location of the buckling in the structure illustrated in FIG. 3. The greater buckling distance reduces the contact force of the probe needles at both of its ends.

Therefore, the contact force acting on the contact pads 6a and 7a is controlled by the buckling distance. After operation, the wafer is retracted from the assembly and the probe needles revert back to their non-buckled or non-deflected state (as illustrated in FIG. 4).

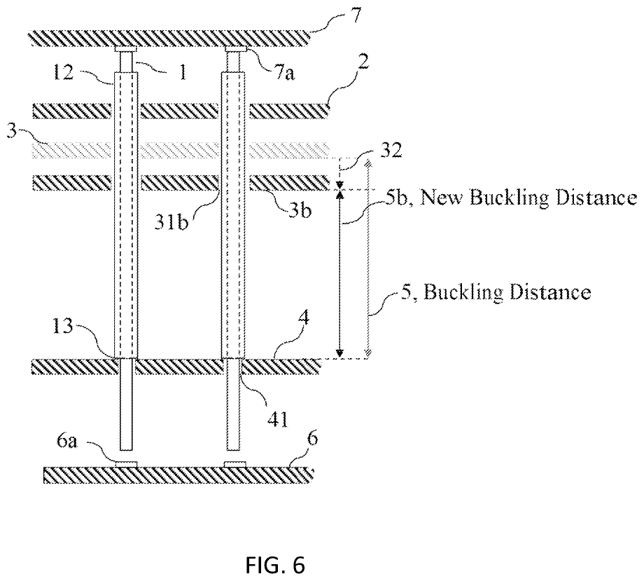

Referring to FIG. 6, the middle guide plate 3 is moveable in either the upward or downward direction (i.e. the Z-direction) as illustrated by 32. Moving the middle guide plate 3 permits the buckling distance 5 to be adjusted. By moving the middle locating guide plate 3 downward in the Z-direction, the buckling distance 5 is decreased. The buckling distance 5 is increased when the middle guide plate 3 is moved upward in the Z-direction. The distance between the middle guide plate 3 and lower guide plate 4 is adjustable using any number of conventional mechanisms. For example, threaded bolts can extend through the middle guide plate 3 and the lower guide plate 4. The threaded bolts can have threaded nuts on the distal sides of the middle guide plate 3 and the lower guide plate 4. The distal sides are the sides facing away from the opposing plate. Advancing the threaded nuts toward the opposing plate reduces the distance between plates. Advancing the threaded nuts away from the opposing plate increases the distance. More complicated mechanisms (i.e. cams or motors that advance the plates together or apart along a spline for example) are also contemplated. Many suitable mechanisms, both manual and automated, are readily apparent to one skilled in the art and are not described in detail herein.

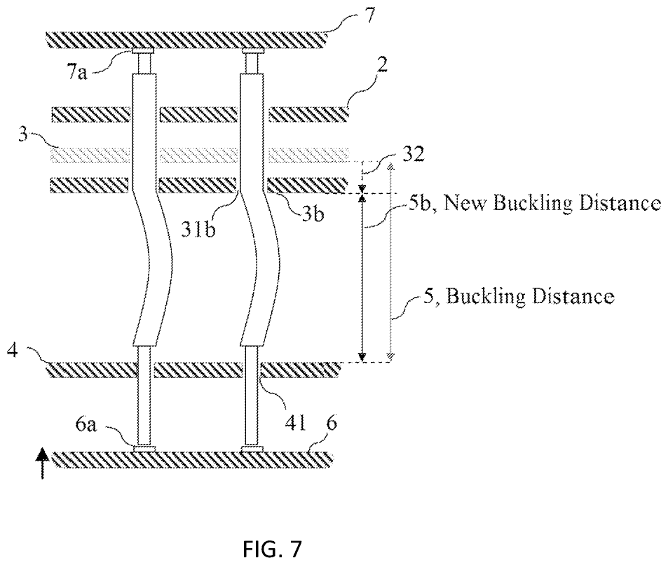

Referring to FIG. 6, decreasing the buckling distance 5b caused the vertical probe needle to have less linear distance for buckling between the middle guide plate 3b and the bottom guide plate 4. This increases the contact force between the probe needles 1 and the contact pads 6a and 7a. Referring to FIG. 7, during operation, the wafer 6 is moved upward in the Z-direction toward the test assembly, so that the wafer pads 6a make contact with the vertical probe needle 1 of the test assembly. The wafer 6 is urged upward further and the body of the probe needles 1 located between the middle guide plate 3b and lower guide plate 4 buckle or deflect. Note that the smaller buckling distance 5b caused the body of the probe needle to buckle or axial deflect in a lower portion of the assembly than the portion of the assembly that is illustrated in FIG. 3. Again, because the buckling distance is less, the probe needles 1 exert a higher contact force at both ends (i.e., on contact pads 6a, 7a). The higher contact force provides stable electrical contact that will conduct electricity to the contact pads of the wafer 6. After operation, the wafer is moved downward in the Z-direction and the probe needles 1 revert back to their non-buckled or non-deflected state (see FIG. 6).

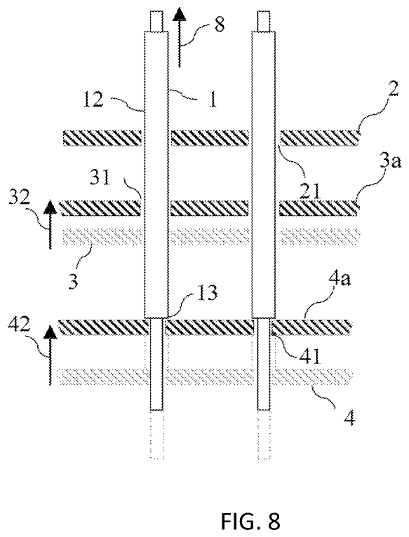

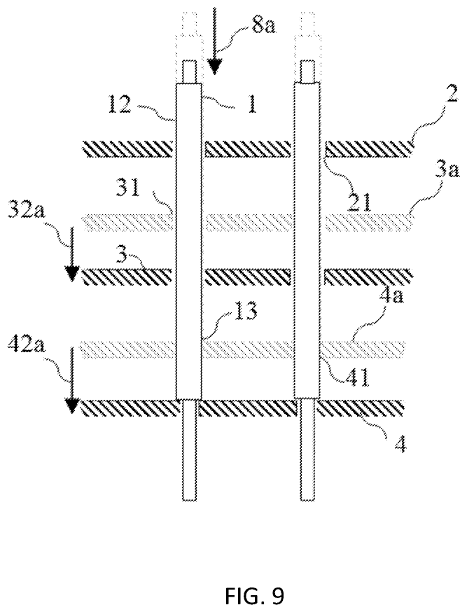

Referring to FIG. 8, when the probe needles 1 require replacement, the top guide plate 2 is decoupled from the PCB 7. The bottom locating guide plate 4 and the middle locating guide plate 3 are moved upward (as illustrated by 42 and 32 respectively) closer to the top guide plate 2. The new position of the bottom locating guide plate (4a), has therefore pushed the vertical probe needles 1 up by pushing the probe needle stopper (13) (i.e. the reduced diameter hole 41 that has a smaller diameter than the probe needle casing 12) upward. The upward position of the middle guide plate holes 31 guides and holds the probe needles non-electrical conductive coating 12. As illustrated by 8 in FIG. 8, a portion or all of the probe needles 1 can be pulled upward and out of the test assembly. Referring to FIG. 9, new vertical probe needles 1 can be inserted downward (as illustrated by 8a) into the test assembly starting from the hole 21 in the top guide plate 2 and down through the hole 31 in the middle guide plate 3a and down through the hole 41 of the bottom guide plate 4a. The advancement of the vertical probe needle 1 through the assembly will be stopped by the stopper 13. The bottom guide plate 4a and middle locating guide plate (3a) are the moved downward in the Z-direction away from the top locating guide plate 2 as shown as bottom guide plate 4 and middle locating guide plate 3 respectively.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A test assembly having a probe head comprising:
a plurality of guide plates at least one of which can be moved in a Z-direction compared with a plane of a substrate for a test assembly, wherein the plurality of guide plates each have a plurality of through holes;
a plurality of probe needles, the probe needles extending from a substrate end of the test assembly toward a distal end, wherein the probe needles at the distal end are brought into contact with contact pads disposed on a wafer to be tested by the test assembly, thereby translating force to the probe needles in contact with contact pads disposed on the substrate;
wherein the at least one guide plate moveable in the Z-direction can be moved closer to or further away from at least one other of the plurality of guide plates in the test assembly thereby adjusting a distance between the at least one guide plate moveable in the Z-direction and an opposing guide plate of the plurality of guide plates;
wherein the distance between the guide plate moveable in the Z-direction and the at least one other guide plate determines a force with which the probe needles contact the contact pads on the wafer and contact pads on the substrate.

2. The test assembly of claim 1 wherein the substrate is one of a printed circuit board and a space transformer.

3. The test assembly of claim 1 wherein the probe needles extend through the through holes of the guide plates.

4. The test assembly of claim 3 wherein a portion of each of the plurality of probe needles are disposed in a sleeve of non-conducting electrical insulation.

5. The test assembly of claim 4 wherein the plurality of probe needles each have a first diameter and the portion of the probe needles disposed in the sleeve of non-conducting electrical insulation have a second diameter, the first diameter being smaller than the second diameter.

6. The test assembly of claim 5 further comprising a bottom guide plate interposed between the guide plate moveable in the Z-direction and the wafer wherein a diameter of the through holes in the bottom guide plate is less than the diameter of the through holes in the guide plate moveable in the Z-direction such that the probe needles disposed in the sleeve and having the second diameter will extend through the through holes of the guide plate moveable in the Z-direction but will not extend through the through holes of the bottom guide plate and wherein the probe needles having the first diameter will extend through the through holes of the guide plate moveable in the Z-direction and also through the through holes of the bottom guide plate.

7. The test assembly of claim 1 comprising a top guide plate interposed between the guide plate moveable in the Z-direction and the substrate and a bottom guide plate that is interposed between the guide plate moveable in the Z-direction and the wafer, wherein the top guide plate is removably fastened to the substrate.

8. The test assembly of claim 6 wherein the plurality of probe needles are retained in the test assembly by the bottom guide plate.

9. The test assembly of claim 6 wherein the guide plate moveable in the Z-direction can be advanced toward or away from an opposing guide plate, wherein a greater distance between the guide plate moveable in the Z-direction and the bottom guide plate is reflective of a lesser contact force between the probe needles and the wafer contact pads and a lesser distance between the guide plate moveable in the Z-direction and the bottom guide plate is reflective of a greater contact force between the probe needles and the wafer contact pads.

10. The test assembly of claim 9 further comprising an adjustment mechanism that permits a position of the guide plate moveable in the Z-direction relative to the opposing guide plate to be adjusted prior to the wafer contact pads being brought into contact with the probe needles, wherein the position is held when the wafer contact pads are brought into contact with the probe needles.

11. The test assembly of claim 10 wherein the adjustment mechanism is a threaded rod along which the guide plate moveable in the Z-direction is advanced for adjustment and threaded nuts that will retain the guide plate moveable in the Z-direction in place.

12. The test assembly of claim 1 wherein the probe needles are a noble metal or a refractory metal.

13. The test assembly of claim 12 wherein the probe needles are one of palladium silver, platinum, rhodium, tungsten, and gold and alloys thereof.

14. The test assembly of claim 13 wherein the probe needles have a diameter of about 20 μm to about 200 μm.

15. A method for operating a test assembly comprising:
providing the test assembly of claim 1, wherein the plurality of guide plates comprises a top guide plate interposed between the guide plate moveable in a Z-direction and the substrate and a bottom guide plate that is interposed between the guide plate moveable in the Z-direction and the wafer;
advancing the contact pads of the wafer into contact with the probe needles; and
continuing to advance the contact pads of the wafer past a point of initial contact with the probe needles such that a portion of the probe needles between the bottom guide plate and the guide plate moveable in the Z-direction bend in response to the force between the wafer contact pads and the probe needles.

16. The method of claim 15 further comprising adjusting a distance between a position of the guide plate moveable in the Z-direction relative to the top guide plate or bottom guide plate, wherein the adjusting step is prior to the advancing step.

17. The method of claim 16 wherein the adjusting step comprises advancing the guide plate moveable in the Z-direction along a rod or spline.
